(19) United States
(12) Patent Application Publication
(10) Pub. No.: US 2011/0248272 A1
(43) Pub. Date: Oct. 13, 2011

(54) ORGANIC EL DISPLAY DEVICE REFLECTIVE ANODE AND METHOD FOR MANUFACTURING THE SAME

(75) Inventors: Mototaka Ochi, Hyogo (JP); Hiroshi Goto, Hyogo (JP); Tomoya Kishi, Hyogo (JP); Nobuyuki Kawakami, Hyogo (JP)

(73) Assignee: Kabushiki Kaisha Kobe Seiko Sho (Kobe Steel, Ltd), Kobe-shi (JP)

(21) Appl. No.: 13/126,126

(22) PCT Filed: Nov. 9, 2009
(86) PCT No.: PCT/JP2009/069069

§ 371 Date: Jun. 29, 2011

(30) Foreign Application Priority Data
Nov. 10, 2008 (JP) 2008-287985
Aug. 6, 2009 (JP) 2009-183741

(51) Int. Cl. H01L 29/786; C23C 14/34; H01L 33/60

(52) U.S. Cl. 257/59; 257/98; 257/72; 438/29; 204/298.12; 257/E33.072; 257/E29.273

(57) ABSTRACT

Provided is a reflective anode for an organic EL display device having a reflective film made from an Al-based alloy which can realize a low contact resistance with an oxide conductive film and achieve an excellent reflectivity. Provided is also a method for manufacturing the reflective anode for an organic EL display device. The method includes: a step of forming an Al-based alloy film containing 0.1 to 2 atomic % of Ni or Co on a substrate; a step of subjecting the Al-based alloy film to a thermal treatment in a vacuum or an inactive gas atmosphere at the temperature of 150 degrees C. or above; and a step of forming an oxide conductive film so as to be in direct contact with the Al-based alloy film.

### TECHNICAL FIELD

The present invention relates to a reflective anode for use in an organic EL display device (particularly, top emission type), a method for manufacturing the same, and the like.

### BACKGROUND ART

An organic electroluminescence (which may be hereinafter described as an “organic EL”) display device which is one of self-emitting type flat panel display devices is an all solid-state flat panel display device in which organic EL devices are arrayed in a matrix on a substrate such as a glass substrate. In the organic EL display device, anodes and cathodes are formed in stripes, the portions of intersection of which correspond to pixels (organic EL devices). The organic EL devices are externally applied with a voltage of several volts, so that a current flows therethrough. As a result, organic molecules are raised to the excited state. When the organic molecules return to the base state (stable state), they emit an extra energy thereof as a light. The luminescence color is inherent in the organic material.

The organic EL devices are devices of self-emitting type and current-driving type. The driving type is classified into a passive matrix type and an active matrix type. The passive matrix type is simple in structure, but has a difficulty in providing full color. On the other hand, the active matrix type can be increased in size, and is also suitable for providing full color, but requires a TFT substrate. For the TFT substrates, a low-temperature polycrystal Si (p-Si), amorphous Si (a-Si), or other TFTs are used.

In the case of the active matrix type organic EL display device, a plurality of TFTs and wires become obstacles, resulting in reduction of the area usable for organic EL pixels. As the driving circuit becomes complicated, and the number of TFTs increases, the effects thereof further increase. In recent years, attention has been focused on the method for improving the aperture ratio not by extracting light from a glass substrate, but by adopting a structure in which light is extracted from the top surface side (top emission system).

With the top emission system, for the anode on the bottom surface, ITO: Indium Tin Oxide excellent in hole injection is used. Whereas, for the cathode on the top surface, it is necessary to use a transparent conductive film. However, ITO has a large work function, and is not suitable for electron injection. Further, ITO is deposited with a sputtering method or an ion beam deposition method. This leads to a fear of damage to the electron transport layer (organic material forming organic EL devices) due to plasma ions and secondary electrons during deposition. For this reason, by forming a thin MG layer or copper phthalocyanine layer on the electron transport layer, electron injection is improved, and the damage is avoided.

Partly for the purpose of reflecting light emitted from an organic EL device, the anode for use in such an active matrix type top-emission organic EL display device forms a lamination structure of a transparent oxide conductive film typified by ITO or IZO: Indium Zinc Oxide and a reflective film (reflective anode). The reflective film for use in the reflective anode is often a reflective metal film of molybdenum, chromium, aluminum, silver, or the like.

In view of only the reflectivity, silver is an ideal material for the reflective film. However, from the viewpoints of the compatibility with the manufacturing process of a thin electron display device, and the material cost, silver has a lot of practical problems. On the other hand, in view of only the reflectivity, aluminum is also favorable as the reflective film. For example, Patent Literature 1 discloses an Al film or an Al—Nd film as the reflective film, and describes to the effect that the Al—Nd film is excellent in reflectivity efficiency and desirable.

However, when an aluminum reflective film is brought in direct contact with an oxide conductive film such as ITO or IZO, the contact resistance is high. This makes it impossible to supply a current enough to inject holes into the organic EL device. In order to avoid this, not aluminum but molybdenum or chromium is employed as the reflective film. Alternatively, molybdenum or chromium is provided as a barrier metal between the aluminum reflective film and the oxide conductive film. As a result, the reflectivity is considerably deteriorated, resulting in reduction of the emission luminance which is the display characteristic. Under such circumstances, Patent Literature 2 proposes an Al—Ni alloy film containing Ni in an amount of 0.1 to 2 at as a reflective electrode (reflective film) capable of omitting a barrier metal.

### CITATION LIST

### Patent Literature

[PTL 1] JP-A-2005-259695
[PTL 2] JP-A-2008-122941

### DISCLOSURE OF THE INVENTION

An organic EL display device is demanded to be further improved in reflectivity of the reflective anode. It is an object of the present invention to provide a reflective anode for an organic EL display device including an Al-based alloy reflective film capable of achieving a low contact resistance with an oxide conductive film such as ITO or IZO, and achieving an excellent reflectivity (reflectivity equal to or higher than that of pure Al).

A method for manufacturing a reflective anode for an organic EL display device of the present invention, which could attain the foregoing object, is characterized by: depositing an Al-based alloy film containing Ni or Co in an amount of 0.1 to 2 at on a substrate; subjecting the Al-based alloy film to a heat treatment at a temperature of 150° C. or more in vacuum or under an inactive gas atmosphere; and depositing an oxide conductive film so as to be in direct contact with the Al-based alloy film.

In the method for manufacturing the reflective anode, it is recommended that after the heat treatment at 150° C. or more of the Al-based alloy film, and before deposition of the oxide conductive film, the Al-based alloy film is subjected to an alkali solution treatment.

A reflective anode for an organic EL display device of the present invention is characterized by including: an oxide conductive film deposited on an Al-based alloy film so as to be indirect contact with the Al-based alloy film, wherein the Al-based alloy film contains Ni or Co in an amount of 0.1 to 2 at %, and the Al-based alloy film have been subjected to a heat treatment at a temperature of 150° C. or more in vacuum or under an inactive gas atmosphere after deposition of the Al-based alloy film and before deposition of the oxide conductive film.

It is preferable that the Al-based alloy film further contains the following elements:

(1) at least one element selected from the group consisting of La, Ge, Cu, Mg, Cr, Mn, Ru, Rh, Pt, Pd, Ir, Ce, Pr, Gd, Tb, Dy, Nd, Ti, Zr, Nb, Mo, Hf, Ta, W, Y, Fe, Sm, Eu, Ho, Er, Tm, Yb, and Lu in a total amount of 0.1 to 2 at %.

(2) La and Ge and/or Cu in a total amount of 0.1 to 2 at %.

Incidentally, in the item (1), it is preferable that Nd is contained in an amount of 0.1 to 1 at %. It is more preferable that Ge is contained in an amount of 0.1 to 1 at % in addition to Nd. Further, in the item (1), it is more preferable that Ni and La are contained.

It is preferable that the arithmetic mean roughness Ra of the surface on the side of the oxide conductive film opposite to the side thereof in contact with the Al-based alloy film is 2 nm or less.

It is preferable that a Ni- or Co-containing precipitate or concentrated layer is formed at the interface of the Al-based alloy film in direct contact with the oxide conductive film.

The present invention also provides a thin-film transistor substrate including the reflective anode for an organic EL display device, an organic EL display device including the thin-film transistor substrate, and further a sputtering target for forming the reflective anode.

In accordance with the present invention, the Al-based alloy film which is a reflective film contains Ni or Co, and thereby can achieve a low contact resistance with an oxide conductive film. Further, before stacking of the oxide conductive film, the Al-based alloy film is subjected to a heat treatment, and thereby can achieve an excellent reflectivity. When the reflective anode of the present invention is used, holes can be injected into an organic light-emitting layer with efficiency due to the low contact resistance. Further, the light emitted from the organic light-emitting layer can be reflected by the reflective film with efficiency. Therefore, it is possible to implement an organic EL display device excellent in emission luminance characteristics.

### BRIEF DESCRIPTION OF THE DRAWINGS

FIG. 1 is a schematic view showing an organic EL display device including a reflective anode of the present invention;

FIG. 2 is a graph showing the reflectivity of a reflective anode including a pure Al film not subjected to pre-annealing as a reflective film, and the reflectivity of a reflective anode including a pure Al film subjected to pre-annealing at 250° C. as a reflective film, wherein the dash-dotted line indicates the reflectivity of the one not subjected to pre-annealing, and the solid line indicates the reflectivity of the one subjected to pre-annealing;

FIG. 3 is a graph showing the reflectivity of a reflective anode including an Al-2 at % Ni-0.35 at % La alloy film not subjected to pre-annealing as a reflective film, and the reflectivity of a reflective anode including an Al-2 at % Ni-0.35 at % La alloy film subjected to pre-annealing at 250° C. as a reflective film, wherein the dash-dotted line indicates the reflectivity of the one not subjected to pre-annealing, and the solid line indicates the reflectivity of the one subjected to pre-annealing;

FIG. 4 is AFM images showing the surface roughness of an ITO film of the reflective anode manufactured in Example 1, wherein FIG. 4A shows an AFM image of a 10 μm×10 μm measurement region, and FIG. 4B is an AFM image of a 2.5 μm×2.5 μm measurement region (reflective film: Al-2 at % Ni-0.35 at % La alloy film, without pre-annealing);

FIG. 5 is AFM images showing the surface roughness of an ITO film of the reflective anode manufactured in Example 1, wherein FIG. 5A shows an AFM image of a 10 μm×10 μm measurement region, and FIG. 5B is an AFM image of a 2.5 μm×2.5 μm measurement region (reflective film: Al-2 at % Ni-0.35 at % La alloy film, with pre-annealing);

FIG. 6 is AFM images showing the surface roughness of an ITO film of the reflective anode manufactured in Example 1, wherein FIG. 5A shows an AFM image of a 10 μm×10 μm measurement region, and FIG. 5B is an AFM image of a 2.5 μm×2.5 μm measurement region (reflective film: pure Ag film, without pre-annealing);

FIG. 7 is a diagram showing the relationship between the pre-annealing temperature and the electric resistivity of a reflective anode manufactured in Example 3;

FIG. 8 is a diagram showing the relationship between the pre-annealing temperature and the electric resistivity of a reflective anode manufactured in Example 3;

FIG. 9 is a graph showing the relationship between the pre-annealing temperature of the reflective anode manufactured in Example 3 and the reflectivity of the reflective anode;

FIG. 10 is a graph showing the relationship between the pre-annealing temperature of the reflective anode manufactured in Example 3 and the reflectivity of the reflective anode;

FIG. 11 is a graph showing the relationship between the pre-annealing temperature of the reflective anode manufactured in Example 3 and the reflectivity of the reflective anode;

FIG. 12 is a graph showing the relationship between the pre-annealing temperature of the reflective anode manufactured in Example 3 and the reflectivity of the reflective anode;

FIG. 13 is a graph showing the results of measurement of the reflectivities (in both of the cases with/without pre-annealing) of an Al-2 at % Ni-0.35 at % La reflective anode;

FIG. 14 is a graph showing the results of measurement of the reflectivities (in both of the cases with/without pre-annealing) of an Al-1 at % Ni-0.35 at % La reflective anode;

FIG. 15 is a graph showing the results of measurement of the reflectivities (in both of the cases with/without pre-annealing) of an Al-1 at % Ni-0.5 at % Cu-0.3 at % La reflective anode;

FIG. 16 is a graph showing the results of measurement of the reflectivities (in both of the cases with/without pre-annealing) of an Al-0.2 at % Co-0.5 at % Ge-0.2 at % La reflective anode;

FIG. 17 is a graph showing the results of measurement of the reflectivities (in both of the cases with/without pre-annealing) of an Al-0.1 at % Ni-0.5 at % Ge-0.5 at % Nd reflective anode;

FIG. 18 is a graph showing the results of measurement of the reflectivities (in both of the cases with/without pre-annealing) of an Al-0.1 at Ni-0.5 at % Ge-0.2 at % Nd reflective anode;

FIG. 19 is a graph showing the results of measurement of the reflectivities (in both of the cases with/without pre-annealing) of an Al-0.1 at % Ni-0.3 at % Ge-0.2 at % Nd reflective anode;

FIG. 20 is a graph showing the results of measurement of the reflectivities (in both of the cases with/without TMAH) of an Al-2 at % Ni-0.35 at % La reflective anode;

FIG. 21 is a graph showing the results of measurement of the reflectivities (in both of the cases with/without TMAH) of an Al-1 at % Ni-0.35 at % La reflective anode;

FIG. 22 is a graph showing the results of measurement of the reflectivities (in both of the cases with/without TMAH) of an Al-1 at % Ni-0.5 at % Cu-0.3 at % La reflective anode;

FIG. 23 is a graph showing the results of measurement of the reflectivities (in both of the cases with/without TMAH) of an Al-0.2 at % Co-0.5 at % Ge-0.2 at % La reflective anode;

FIG. 24 is a graph showing the results of measurement of the reflectivities (in both of the cases with/without TMAH) of an Al-0.1 at % Ni-0.5 at % Ge-0.5 at % Nd reflective anode;

FIG. 25 is a graph showing the results of measurement of the reflectivities (in both of the cases with/without TMAH) of an Al-0.1 at % Ni-0.5 at % Ge-0.2 at % Nd reflective anode; and

FIG. 26 is a graph showing the results of measurement of the reflectivities (in both of the cases with/without TMAH) of an Al-0.1 at % Ni-0.3 at % Ge-0.2 at % Nd reflective anode.

### BEST MODE FOR CARRYING OUT THE INVENTION

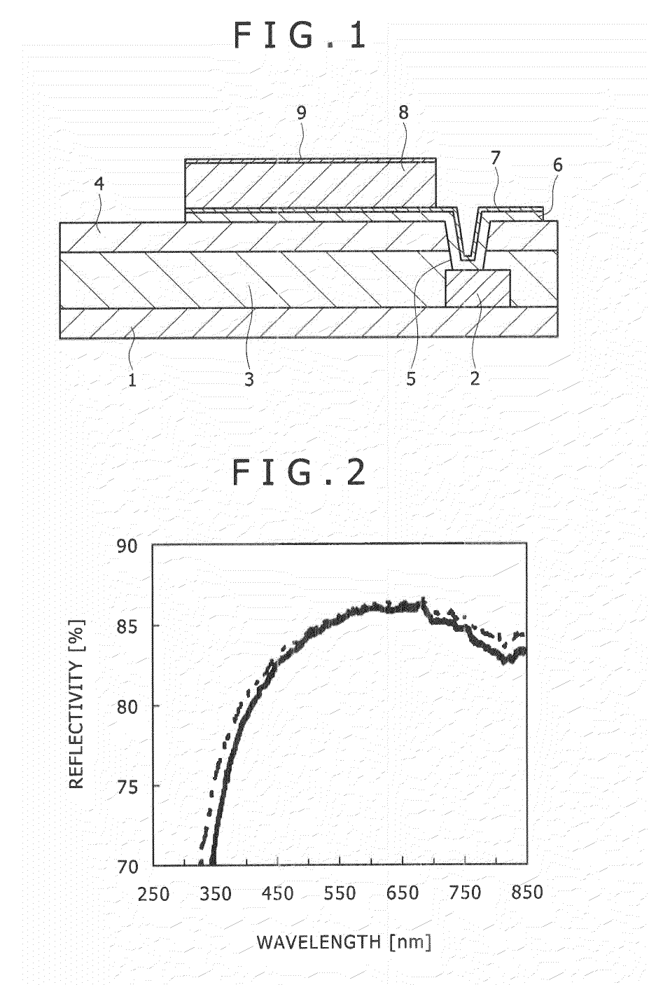

First, referring to FIG. 1, a description will be given to the outline of an organic EL display device including a reflective anode of the present invention. In FIG. 1, on a substrate 1, a TFT 2 and a passivation film 3 are formed. Further, thereon, a planarization layer 4 is formed. On the TFT 2, a contact hole 5 is formed. Source/drain electrodes (not shown) of the TFT2 and an Al-based alloy film 6 are electrically connected through the contact hole 5.

The Al-based alloy film is preferably deposited by a sputtering method. The preferable deposition conditions are as follows:

Substrate temperature: 25° C. or more and 200° C. or less (more preferably 150° C. or less);

Film thickness of Al-based alloy film: 50 nm or more (more preferably 100 nm or more) and 300 nm or less (more preferably 200 nm or less)

Immediately on the Al-based alloy film 6, an oxide conductive film 7 is formed. The Al-based alloy film 6 and the oxide conductive film 7 form the reflective anode of the present invention. This is referred to as the reflective anode for the following reason: the Al-based alloy film 6 and the oxide conductive film 7 act as the reflective electrode of the organic EL device. In addition, the Al-based alloy film 6 and the oxide conductive film 7 are electrically connected to the source/drain electrodes of the TFT 2, and hence act as the anode.

The oxide conductive film is preferably deposited by a sputtering method. The preferable deposition conditions are as follows:

Substrate temperature: 25° C. or more and 150° C. or less (more preferably 100° C. or less);

Film thickness of oxide conductive film: 5 nm or more (more preferably 10 nm or more) and 100 nm or less (more preferably 50 nm or less)

On the oxide conductive film 7, an organic light-emitting layer 8 is formed. Further, thereon, a cathode 9 is formed. Such an organic EL display device can achieve an excellent emission luminance because the light emitted from the organic light-emitting layer 8 is reflected by the reflective anode of the present invention with efficiency. Incidentally, a higher reflectivity is more desirable. The reflectivity is demanded to be generally 85% or more, and preferably 87% or more.

The present invention is characterized in that the Al-based alloy film which is a reflective film is heat-treated at a heat treatment temperature: 150° C. or more in vacuum or under an inactive gas (e.g., nitrogen) atmosphere before being brought in direct contact with the oxide conductive film. Incidentally, in this description, heat-treating of the Al-based alloy film before the formation of the oxide conductive film may be abbreviated as “pre-annealing”. Whereas, heat-treating of the reflective anode (Al-based alloy film+oxide conductive film) after the formation of the oxide may be abbreviated as “post-annealing”.

In the present invention, a reflective anode with an excellent reflectivity can be formed by pre-annealing. The mechanism by which the reflectivity is improved by pre-annealing can be considered as follows.

The surface of the Al-based alloy film (matrix Al) is oxidized and reformed by pre-annealing, resulting in reduction of the interface energy between the Al-based alloy film and the oxide conductive film. When the interface energy is reduced, the wettability of the oxide conductive film is improved, which prevents aggregation of the oxide conductive film. As a result, the film quality of the oxide conductive film becomes favorable, resulting in an improvement of the reflectivity. Further, the improved film quality of the oxide conductive film results in reduction of the surface roughnesses (particularly, arithmetic mean roughness Ra) of the surface (i.e., the surface not in contact with the Al-based alloy film). Accordingly, the reflectivity is improved. Further, pre-annealing also inhibits generation of whisker of the oxide conductive film. This also results in an improvement of the reflectivity.

Further, by pre-annealing, Ni- or Co-containing precipitates (e.g., intermetallic compounds) or concentrated layer is formed on the Al-based alloy film surface (i.e., the interface between the Al-based alloy film and the oxide conductive film). This results in reduction of the contact resistance. In general, when an oxide layer (AlOx) is formed at the Al-based alloy film interface due to mutual diffusion between the Al-based alloy film and the oxide conductive film, the contact resistance is increased. However, when the intermetallic compound or the like is present, only a thin (10-nm or less) AlOx is formed on the surface of the intermetallic compound. For this reason, the contact resistance can be reduced.

In order to further improve the physical contact between the Al-based alloy film and the oxide conductive film, the following is also effective: immediately before bringing the Al-based alloy film in contact with oxide conductive film, the Al-based alloy film surface is subjected to light etching with an alkali solution such as TMAH: Tetra-Mechyl-Ammonium-Hydroxide, thereby to remove AlOx on the surface.

The reflective anode of the present invention subjected to pre-annealing as described above can achieve the following two effects: the aggregation of the oxide conductive film is inhibited, so that an excellent reflectivity is exhibited; and a low contact resistance is shown due to precipitation of the intermetallic compounds.

The pre-annealing temperature is 150° C. or more, preferably 200° C. or more, more preferably 220° C. or more, and further preferably 250° C. or more. Further, the pre-annealing temperature is preferably 400° C. or less, and more preferably 350° C. or less. When the pre-annealing temperature is too low, the effects of interface energy reduction and the improvement of the wettability of the oxide conductive film become insufficient. On the other hand, when the pre-annealing temperature is too high, hillocks (bump-like protrusions) are generated on the Al-based alloy film surface.

The pre-annealing time is preferably about 10 minutes or more, more preferably about 15 minutes or more, and preferably about 120 minutes or less, and more preferably about 60 minutes or less. Precipitation of the intermetallic compounds by pre-annealing requires a certain degree of time. On the other hand, when the pre-annealing time is too long, the step takes time. This is not desirable in manufacturing.

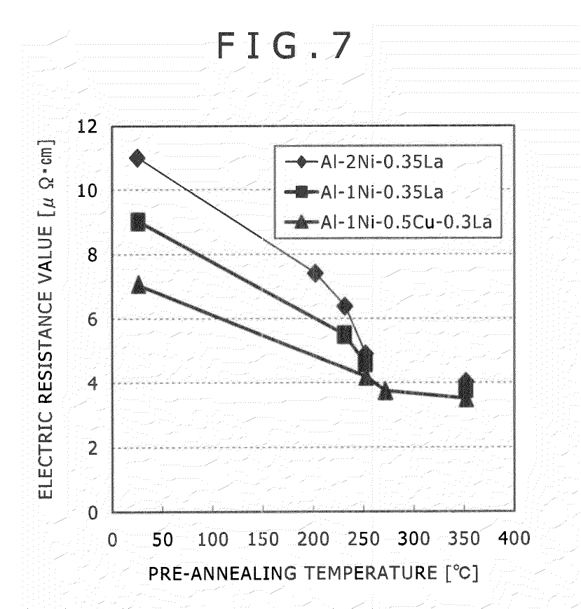

PTL 2 discloses that the contact resistance can be reduced by subjecting an Al—Ni alloy film containing Ni in an amount of 0.1 to 2 at % to a low-temperature heat treatment. However, in the description of the manufacturing method by reference to FIG. 7 of PTL 2, it is disclosed only that an Al-based alloy film is deposited after deposition of an ITO film. Namely, comprehensively, from PTL 2, there can be read the configuration in which a heat treatment (post-annealing) is performed with the ITO film and the reflective film being in direct contact with each other, and the effect of enabling a low contact resistance by post-annealing. However, from PTL 2, there cannot be read the configuration in which the Al-based alloy reflective film is pre-annealed before the ITO film deposition, and the effect of enabling an excellent reflectivity by pre-annealing.

It is desirable that the Al-based alloy film is subjected to an alkali solution treatment after pre-annealing and before deposition of the oxide conductive film. This is because the alkali solution treatment remarkably reduces the contact resistance value between the Al-based alloy film and the oxide conductive film. Any alkali solution treatment is acceptable so long as it can bring an alkaline solution into contact with the surface of the Al-based alloy film. As the alkali solution, for example, a TMAH aqueous solution is usable.

Incidentally, also in the present invention, in addition to pre-annealing, post-annealing may be performed. The post-annealing temperature is preferably 200° C. or more, and more preferably 250° C. or more, and preferably 350° C. or less, and more preferably 300° C. or less. The post-annealing time is preferably about 10 minutes or more, and more preferably about 15 minutes or more, and preferably about 120 minutes or less, and more preferably about 60 minutes or less.

In the reflective anode of the present invention, the Al-based alloy film contains Ni or Co. In order for the intermetallic compound containing Ni or Co to effectively exert an action of reducing the contact resistance, the amount of Ni or Co contained in Al is required to be 0.1 at % or more. On the other hand, when the Ni or Co content exceeds 2 at %, the reflectivity of the Al-based alloy film itself becomes low, and the Al-based alloy film cannot be put into practical use. The content of Ni or Co contained in Al is 0.1 at % or more (preferably 0.2 at % or more, and more preferably 0.3 at % or more), and 2 at % or less (preferably 1.5 at % or less, and more preferably 1.0 at % or less).

When the Al-based alloy film is allowed to further contain at least one element selected from the group consisting of La, Ge, Cu, Mg, Cr, Mn, Ru, Rh, Pt, Pd, Ir, Ce, Pr, Gd, Tb, Dy, Nd, Ti, Zr, Nb, Mo, Hf, Ta, W, Y, Fe, Sm, Eu, Ho, Er, Tm, Yb, and Lu (which may be hereinafter abbreviated as “group X”), the heat resistance of the Al-based alloy film is improved. This effectively prevents the formation of hillocks (bump-like projections) on the surface.

When the content of elements belonging to the group X is less than 0.1 at %, the heat resistance improving action cannot be effectively exhibited. From only the viewpoint of heat resistance, a higher content of elements belonging to the group X is more desirable. However, when the content exceeds 2 at %, the electric resistivity of the Al-based alloy film itself increases. Thus, the content thereof is preferably 0.1 at % or more (more preferably 0.2 at % or more), and preferably 2 at % or less (more preferably 0.8 at % or less). These elements may be added alone, or may be used in combination of two or more thereof. When two or more elements are added, the total content of respective elements may be controlled so as to satisfy the foregoing range.

Of the elements belonging to the group X, those preferable from the viewpoint of improvement of the heat resistance are Cr, Ru, Rh, Pt, Pd, Ir, Dy, Ti, Zr, Nb, Mo, Hf, Ta, W, Y, Fe, Eu, Ho, Er, Tm, and Lu. Ir, Nb, Mo, Hf, Ta, and W are more preferable. Whereas, those preferable from the viewpoints of not only the improvement of the heat resistance but also the reduction of the electric resistivity are La, Cr, Mn, Ce, Pr, Gd, Tb, Dy, Nd, Zr, Nb, Hf, Ta, Y, Sm, Eu, Ho, Er, Tm, Yb, and Lu. La, Gd, Tb, and Mn are more preferable.

Particularly, when the Al-based alloy film is allowed to contain La and Ge and/or Cu, the characteristics such as reflectivity, contact resistance, and heat resistance are further enhanced. The total content of these elements is equal to the total content of elements of the group X.

Of the elements of the group X, Nd is preferably selected. The preferable content of Nd is 0.1 at % or more (more preferably 0.2 at % or more), and preferably 1 at % or less, (more preferably 0.8 at % or less). Further, it is further preferable that Ge is also selected in addition to Nd. The preferable content of Ge is 0.1 at % or more (more preferably 0.2 at % or more), and preferably 1 at % or less (more preferably 0.8 at % or less).

The arithmetic mean roughness Ra of the surface of the oxide conductive film not in contact with the Al-based alloy film is preferably 2 nm or less, and more preferably 1.9 nm or less. The organic light-emitting layer formed on the oxide conductive film is very thin, and hence tends to be affected by the surface roughness of the oxide conductive film. For this reason, when the surface roughnesses (particularly, the arithmetic mean roughness Ra) of the oxide conductive film are large, a pin hole tends to be generated in the organic light-emitting layer. The pin hole causes an image defect referred to as a dark spot in an organic EL display device. Further, when the surface roughness of the oxide conductive film is large, the reflectivity of the reflective anode is reduced.

The term “arithmetic mean roughness Ra” in the present invention means the “value obtained by averaging absolute values of the differences in height between the average line and the roughness curve”. The Ra of the oxide conductive film can be detected in the following manner: after peeling the overlying organic light-emitting layer, for the surface of the oxide conductive film (i.e., the surface not in contact with the Al-based alloy film), the surface roughness was measured by means of an AFM (Atomic Force Microscope).

The reflective anode of the organic EL display device of the present invention shows an excellent reflectivity and a low contact resistance. For this reason, this is preferably applied to a thin-film transistor substrate, and further a display device.

### EXAMPLES

Below, the present invention will be described more specifically by way of examples. The present invention is not limited to the following examples. It is naturally understood that the present invention can also be practiced by being appropriately changed within a range adaptable to the gist described above and below. All of these are included in the technical range of the present invention.

### Example 1

Using a non-alkaline glass plate (gage: 0.7 mm) as a substrate, a SiN film (film thickness: 300 nm) of a passivation film was deposited on the surface by means of plasma CVD equipment. The deposition conditions were as follows. Substrate temperature: 280° C., gas ratio: SiH₄/NH₃/N₂=125/6/185, pressure: 137 Pa, and RF power: 100 W. Further, on the surface, an Al-based alloy film (film thickness: about 100 nm) of a reflective film was deposited by a sputtering method. The deposition conditions were as follows. Substrate temperature: 25° C., pressure: 2 mTorr, and DC power: 260 W. Whereas, for comparison, a pure Al film (film thickness: about 100 nm) was similarly deposited with a sputtering method. The composition of the reflective film thus deposited was identified by means of an electron excitation type characteristic X-ray analysis.

Some of the Al-based alloy films and the pure Al film monolayer deposited as described above were each measured for the reflectivity before the heat treatment, and the reflectivities after each 30-minute heat treatment (pre-annealing) at 200° C., 220° C., and 250° C. in the following manner. Table 1 shows the results.

<Measurement of Reflectivity>

Using a visible/UV spectrophotometer “V-570” manufactured by JASCO Corp., the spectral reflectivity at a measurement wavelength within the range of 1000 to 250 nm was measured. Specifically, the value obtained by measuring the reflection light intensity of the sample with respect to the reflection light intensity of the reference mirror is referred to as “reflectivity”.

Further, the reflective films (Al-based alloy films, pure Al films, and pure Ag films) deposited as described above were divided into groups A, B, and C. Then, only the reflective films of the group C were subjected to a heat treatment (pre-annealing) for 30 minutes at the temperatures shown in Table 2 under a nitrogen atmosphere before deposition of the ITO film.

On each reflective film of the groups A, B, and C, an ITO film (film thickness: 10 nm) was deposited by a sputtering method to form a reflective anode (reflective film+oxide conductive film). The deposition conditions were as follows. Substrate temperature: 25° C., pressure: 0.8 mTorr, and DC power: 150 W. For the groups A and B, after sputtering deposition, each reflective film was not taken out. Thus, the inside of the chamber of the sputtering device was still set in vacuum state, wherein the ITO film was continuously deposited. On the other hand, for the group C, each reflective film was taken out from the chamber once, and was subjected to pre-annealing. Then, the ITO film was deposited. After deposition of the ITO film, each reflective anode of the groups B and C was subjected to a heat treatment (post-annealing) for 30 minutes at 250° C. under a nitrogen atmosphere.

The reflectivity of each reflective anode manufactured as described above was measured in the foregoing manner. Table 2 shows the results. Incidentally, in Table 2, the evaluation results of rating on the following criteria are also shown <evaluation criteria for the reflectivity (λ=550 nm)>

AA: 87%≦reflectivity

BB: 85%≦reflectivity<87%

CC: reflectivity<85%

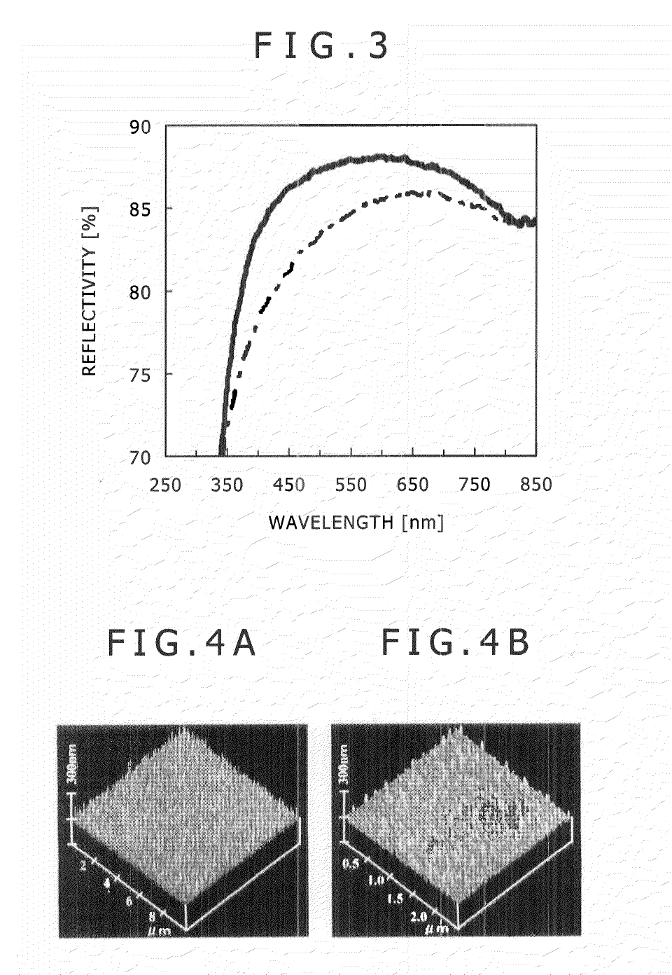

Further, FIG. 2 is a graph showing the reflectivity of a reflective anode including a pure Al film subjected to pre-annealing at 250° C. (sample No. 2-10) as a reflective film, or a reflective anode including a pure Al film not subjected to pre-annealing (sample No. 2 to 4) as a reflective film. Whereas, FIG. 3 is a graph showing the reflectivity of a reflective anode including an Al-2 at % Ni-0.35 at % La alloy film subjected to pre-annealing at 250° C. (sample No. 2-13) as a reflective film, or a reflective anode including an Al-2 at % Ni-0.35 at % La alloy film not subjected to pre-annealing (sample No. 2-7) as a reflective film.

Further, for each reflective anode of the groups A, B, and C, the contact resistance was measured in the following manner. Table 2 shows the results. Incidentally, the contact resistance values shown in Table 2 vary from one another. This is due to the degree of formation and variations in distribution of precipitates.

<Measurement of Contact Resistance Value>

In the same manner as described above, on each non-alkaline glass substrate, a SiN film, a reflective film, and an ITO film were deposited in this order. The resulting sample was etched to form a contact resistance measurement pattern (contact areas: 20, 40, and 80 μm□). Further, as described above, the group B was subjected to only post-annealing, and the group C was subjected to pre-annealing and post-annealing. The contact resistance value of each sample thus manufactured was measured with a four-terminal Kelvin method.

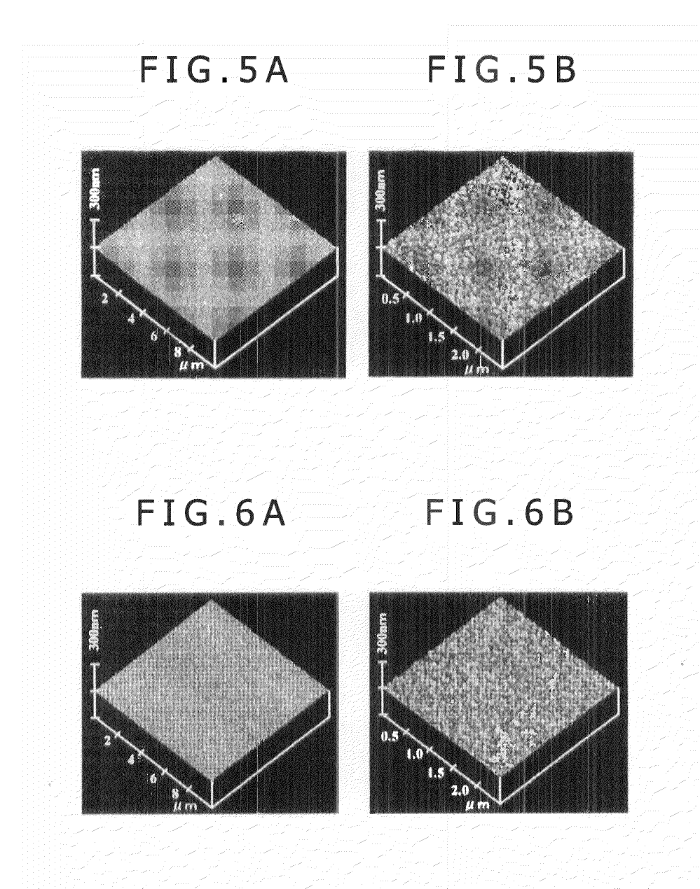

Further, the ITO film surface of the reflective anode using the Al-2 at % Ni-0.35 at % La alloy film subjected to pre-annealing (sample No. 2-13), and the ITO film surface of the reflective anode using the Al-2 at % Ni-0.35 at % La alloy film (sample No. 2-7) or the pure Ag film (sample No. 2-23) not subjected to pre-annealing were measured by means of an AFM (Atomic Force Microscope). Thus, each arithmetic mean roughness Ra and maximum height Rmax thereof were calculated. Herein, the term “maximum height Rmax” means the “maximum value of five distances when the measurement length is divided into five equal parts, and the distances between the highest tops and the deepest bottoms of respective sections are determined”. Table 3 and FIGS. 4A and 4B to 6A and 6B show the results. Incidentally, “10 μm×10 μm” and “2.5 μm×2.5 μm” shown in Table 3 represent the measurement regions of the AFM.

TABLE 1
Reflectivity at reflective film monolayer

| | | Reflectivity (%) λ = 550 nm | | | |
|---|---|---|---|---|---|
| Sample | | Without pre- | 200° C. | 220° C. | 250° C. |
| No. | Reflective film*¹ | annealing | pre-annealing | pre-annealing | pre-annealing |
| 1-1 | Pure Al | 92 | 91.5 | 91 | 90.5 |
| 1-2 | Al—1Ni—0.35La | 89.6 | 90 | 90.5 | 90 |
| 1-3 | Al—2Ni—0.35La | 88.6 | 90.2 | 90.5 | 90 |
| 1-4 | Al—1Ni—0.5Cu—0.3La | 89.7 | 90 | 90.3 | 90.7 |
| 1-5 | Al—1Ni—0.6Nd | 90 | 88.7 | 88.8 | 90 |
| 1-6 | Al—0.2Co—0.5Ge—0.2La | 89.7 | 89.2 | 89.3 | 89.8 |

*¹Unit of component composition: at %

TABLE 2
Reflectivity and contact resistance value of reflective anode (reflective film + ITO)

| | | | | | | | Contact resistance | Resistance |
|---|---|---|---|---|---|---|---|---|
| Sample | | | Pre-annealing | Post-annealing | Reflectivity (%) | Reflectivity | value*² | value |
| No. | Reflective film*¹ | Class. | temperature (° C.) | temperature (° C.) | λ = 550 nm | evaluation | (μΩ/cm²) | evaluation |
| 2-1 | Pure Al | A | — | — | 82.9 | X | >100k | X |
| 2-2 | Al—1Ni—0.35La | A | — | — | 83 | X | >100k | X |
| 2-3 | Al—2Ni—0.35La | A | — | — | 82.4 | X | >100k | X |
| 2-4 | Pure Al | B | — | 250 | 85.5 | Δ | >100k | X |
| 2-5 | Al—0.2Ni—0.35La | B | — | 250 | 85.7 | Δ | >100k | X |
| 2-6 | Al—1Ni—0.35La | B | — | 250 | 85.8 | Δ | >100k | X |
| 2-7 | Al—2Ni—0.35La | B | — | 250 | 85.2 | Δ | >100k | X |
| 2-8 | Al—2Ni—0.1La | B | — | 250 | 85.7 | Δ | >100k | X |
| 2-9 | Al—2Ni—0.5La | B | — | 250 | 85.2 | Δ | >100k | X |
| 2-10 | Pure Al | C | 250 | 250 | 85.4 | Δ | >100k | X |
| 2-11 | Al—0.2Ni—0.35La | C | 250 | 250 | 88 | ◯ | 2000-7000 | X |
| 2-12 | Al—1Ni—0.35La | C | 250 | 250 | 88.8 | ◯ | 175-230 | ◯ |
| 2-13 | Al—2Ni—0.35La | C | 250 | 250 | 88.7 | ◯ | 170-220 | ◯ |
| 2-14 | Al—2Ni—0.1La | C | 250 | 250 | 88.5 | ◯ | 120-180 | ◯ |
| 2-15 | Al—2Ni—0.5La | C | 250 | 250 | 88.2 | ◯ | 200-250 | ◯ |
| 2-16 | Al—1Ni—0.5Cu—0.3La | C | 250 | 250 | 88.6 | ◯ | 270-330 | ◯ |
| 2-17 | Al—0.2Co—0.5Ge—0.2La | C | 250 | 250 | 87 | ◯ | 210-250 | ◯ |
| 2-18 | Al—2Ni—0.35La | C | 100 | 250 | 86.5 | ◯ | 700-10000 | X |
| 2-19 | Al—2Ni—0.35La | C | 150 | 250 | 87.7 | ◯ | 400-600 | ◯ |
| 2-20 | Al—2Ni—0.35La | C | 200 | 250 | 88.2 | ◯ | 200-250 | ◯ |
| 2-21 | Al—2Ni—0.35La | C | 300 | 250 | 88.5 | ◯ | 140-180 | ◯ |
| 2-22 | Pure Ag | A | — | — | 95.2 | ◯ | — | — |
| 2-23 | Pure Ag | B | — | 250 | 95.1 | ◯ | — | — |

*¹Unit of component composition: at %
*²┌kj = ┌×1000┘

TABLE 3
Surface roughness and reflectivity of reflective anode (reflective film + ITO)

| Sample | | | Ra (nm) | | Rmax (nm) | | Reflectivity(%) |
|---|---|---|---|---|---|---|---|
| No. | Reflective film *¹ | Classification | 10 × 10 μm | 2.5 × 2.5 μm | 10 × 10 μm | 2.5 × 2.5 μm | λ = 550 nm |
| 2-7 | Al—2Ni—0.35La | B (Without pre-annealing) | 7.1 | 7.1 | 126.6 | 115.5 | 85.2 |
| 2-13 | Al—2Ni—0.35La | C (With pre-annealing) | 1.7 | 1.9 | 39.9 | 19.4 | 88.7 |
| 2-23 | Pure Al | B (Without pre-annealing) | 1.5 | 1.6 | 21.9 | 19.0 | 95.1 |

*¹ Unit of component composition: at %

As apparent from the results of Table 2, the Al-based alloy film (reflective film) satisfying the composition requirements of the present invention can achieve an excellent reflectivity by being subjected to pre-annealing. Further, the reflective anode of the present invention shows a low contact resistance value. The reflective anodes of the group B (only post-annealing) each have an improved reflectivity than those of the group A (without annealing). This is because the ITO film has been crystallized by post-annealing.

Further, the results of Table 3 indicate the following: the surface roughnesses (Ra and Rmax) of the ITO film of the reflective anode are reduced by performing pre-annealing; accordingly, an excellent reflectivity can be achieved.

### Example 2

Then, as shown in Table 4, there were deposited various reflective anodes (sample Nos. 3-1 to 3-12) with the same compositions as those of the reflective anodes of Example 1, but subjected to different treatment conditions after deposition, and various reflective anodes (sample Nos. 3-13 to 3-25) containing Nd and subjected to different treatment conditions after deposition. The reflective anodes containing Nd are: (1) Al-0.1 at % Ni-0.5 at % Ge-0.5 at % Nd; (2) Al-0.1 at % Ni-0.3 at % Ge-0.2 at % Nd; and (3) Al-0.1 at % Ni-0.5 at % Ge-0.2 at % Nd. The composition of each reflective anode, the treatment conditions after deposition, and the measurement results of reflectivity and contact resistance value of each reflective anode are shown similarly as in Table 2 of Example 1. The classification into A to C of Table 2 (groups A, B, and C) is done according to whether or not pre-annealing or post-annealing after deposition of the reflective anode is performed. However, in Table 4, a group D and a group E are further added. The group D and the group E are subjected to both of pre-annealing and post-annealing. The group D is subjected to an alkali solution treatment for 25 seconds after pre-annealing. The group E is subjected to an alkali solution treatment for 50 seconds after pre-annealing. The alkali solution treatment of Example 2 is an alkali solution treatment (TMAH treatment) using a tetramethylammonium hydroxide (TMAH) aqueous solution with a concentration of 0.4 mass % as an alkali solution. The evaluation criteria for the reflectivity and the contact resistance value are the same as in Table 2. The conditions not clearly shown in Table 4 are basically the same as in Table 2.

TABLE 4

| | Corre- | | | Pre- | | Post- | | | Contact | |
|---|---|---|---|---|---|---|---|---|---|---|
| | sponding | | | annealing | TMAH | annealing | Reflec- | Reflec- | resistance | Resistance |
| Sample | No. of | Composition of | Group- | temperature | treatment | temperature | tivity (%) | tivity | value *2 | value |
| No. | Table 2 | reflective film *1 | ing | (° C.) | (sec) | (° C.) | λ = 550 nm | evaluation | (μΩ/cm²) | evaluation |
| 3-1 | 2-3 | Al—2Ni—0.35La | A | — | — | — | 82.4 | X | >100k | X |
| 3-2 | 2-7 | Al—2Ni—0.35La | B | — | — | 250 | 85.2 | Δ | >100k | X |
| 3-3 | 2-13 | Al—2Ni—0.35La | C | 250 | — | 250 | 88.7 | ◯ | 170-220 | ◯ |
| 3-4 | — | Al—2Ni—0.35La | D | 250 | 25 | 250 | 86 | Δ | 100-180 | ◯ |
| 3-5 | — | Al—2Ni—0.35La | E | 250 | 50 | 250 | 84.8 | Δ | 50-100 | ◯ |
| 3-6 | 2-12 | Al—1Ni—0.35La | C | 250 | — | 250 | 88.8 | ◯ | 175-230 | ◯ |
| 3-7 | — | Al—1Ni—0.35La | D | 250 | 25 | 250 | 86.1 | Δ | 130-210 | ◯ |
| 3-8 | 2-16 | Al—1Ni—0.5Cu—0.3La | C | 250 | — | 250 | 88.6 | ◯ | 270-330 | ◯ |
| 3-9 | — | Al—1Ni—0.5Cu—0.3La | D | 250 | 25 | 250 | 85.6 | Δ | 110-170 | ◯ |
| 3-10 | 2-17 | Al—0.2Co—0.5Ge—0.2La | C | 250 | — | 250 | 87 | ◯ | 210-250 | ◯ |
| 3-11 | — | Al—0.2Co—0.5Ge—0.2La | D | 250 | 25 | 250 | 87.2 | ◯ | 100-160 | ◯ |
| 3-12 | — | Al—0.2Co—0.5Ge—0.2La | E | 250 | 50 | 250 | 87 | ◯ | 50-120 | ◯ |
| 3-13 | — | Al—0.1Ni—0.5Ge—0.5Nd | C | 250 | — | 250 | 87.1 | ◯ | 250-310 | ◯ |
| 3-14 | — | Al—0.1Ni—0.5Ge—0.5Nd | D | 250 | 25 | 250 | 87.2 | ◯ | 150-220 | ◯ |
| 3-15 | — | Al—0.1Ni—0.5Ge—0.5Nd | E | 250 | 50 | 250 | 87.3 | ◯ | 90-150 | ◯ |
| 3-16 | — | Al—0.1Ni—0.5Ge—0.2Nd | C | 250 | — | 250 | 87.1 | ◯ | 220-270 | ◯ |
| 3-17 | — | Al—0.1Ni—0.5Ge—0.2Nd | D | 250 | 25 | 250 | 87.3 | ◯ | 110-180 | ◯ |
| 3-18 | — | Al—0.1Ni—0.5Ge—0.2Nd | E | 250 | 50 | 250 | 86.2 | Δ | 60-120 | ◯ |
| 3-19 | — | Al—0.1Ni—0.3Ge—0.2Nd | C | 250 | — | 250 | 87.7 | ◯ | 250-300 | ◯ |
| 3-20 | — | Al—0.1Ni—0.3Ge—0.2Nd | D | 250 | 25 | 250 | 87.5 | ◯ | 130-200 | ◯ |
| 3-21 | — | Al—0.1Ni—0.3Ge—0.2Nd | E | 250 | 50 | 250 | 87.8 | ◯ | 75-140 | ◯ |
| 3-22 | — | Al—0.1Ni—0.5Ge—0.2Nd | C | 100 | — | 250 | 86.4 | Δ | 600-950 | ◯ |
| 3-23 | — | Al—0.1Ni—0.5Ge—0.2Nd | C | 150 | — | 250 | 86.7 | Δ | 300-500 | ◯ |
| 3-24 | — | Al—0.1Ni—0.5Ge—0.2Nd | C | 200 | — | 250 | 87 | ◯ | 250-330 | ◯ |
| 3-25 | — | Al—0.1Ni—0.5Ge—0.2Nd | C | 300 | — | 250 | 87.2 | ◯ | 220-280 | ◯ |

*1 Unit of component composition: at %
*2 ┌kj = ┌×1000┘

As indicated from the sample Nos. 3-1 to 3-12 of Table 4, for the sample Nos. 3-4 and 3-5 subjected to the TMAH treatment, each reflective anode tends to have a slightly lower reflectivity, but has a considerably lower contact resistance value as compared with the sample No. 3-3 not subjected to the TMAH treatment. The sample No. 3-7, sample No. 3-9, and sample Nos. 3-11 and 3-12 are also similarly improved.

As indicated from the sample Nos. 3-13 to 3-25 of Table 4, each reflective anode containing Nd can also obtain a high reflectivity and a low contact resistance value as with Example 1 (reflective anode not containing Nd).

### Example 3

For further detailed inspection of the reflective anodes in accordance with the present invention, tests were performed on: (1) the relationship between the pre-annealing temperature and the electric resistivity; (2) the relationship between the pre-annealing temperature and the reflectivity; (3) the effects of pre-annealing exerted on the reflectivity; and (4) the effects of the alkali solution treatment exerted on the reflectivity. Incidentally, unless otherwise specified, various conditions such as pre-annealing time and type of the alkali solution used are the same as the conditions in Example 2.

(1) Relationship Between Pre-Annealing Temperature and Electric Resistivity

FIGS. 7 and 8 show the results of measurement of the electric resistivities of the reflective anodes subjected to different pre-annealing temperatures for seven types of reflective anodes (sample Nos. 4-1 to 4-7) shown in Table 5. FIG. 8 includes the measurement results of the electric resistivities of the reflective anodes containing Nd (sample Nos. 4-5 to 4-7). As indicated from all the results, the electric resistivity of each reflective anode was reduced by performing pre-annealing. Further, it has been shown that, the higher the pre-annealing temperature is, the more remarkably the effects are exhibited.

TABLE 5

| Sample No. | Composition (unit: at %) | as-depo | 200° C. | 230° C. | 250° C. | 270° C. | 350° C. |
|---|---|---|---|---|---|---|---|
| 4-1 | Al—2Ni—0.35La | 11.0 | 7.4 | 6.4 | 4.9 | | 4.0 |
| 4-2 | Al—1Ni—0.35La | 9.0 | | 5.5 | 4.6 | | 3.8 |
| 4-3 | Al—1Ni—0.5Cu—0.3La | 8.8 | | 4.9 | 4.6 | | 3.7 |
| 4-4 | Al—0.2Co—0.5Ge—0.2La | 7.1 | | | 4.2 | 3.7 | 3.5 |
| 4-5 | Al—0.1Ni—0.5Ge—0.5Nd | 9.3 | 6.4 | 5.2 | 4.9 | | |
| 4-6 | Al—0.1Ni—0.5Ge—0.2Nd | 7.3 | 5.2 | 4.7 | 4.4 | 3.6 | 3.3 |
| 4-7 | Al—0.1Ni—0.3Ge—0.2Nd | 6.5 | 5.3 | 4.7 | 4.5 | | |

Unit: νΩ · cm
as-depo: meaning without pre-annealing

(2) Relationship Between Pre-Annealing Temperature and Reflectivity

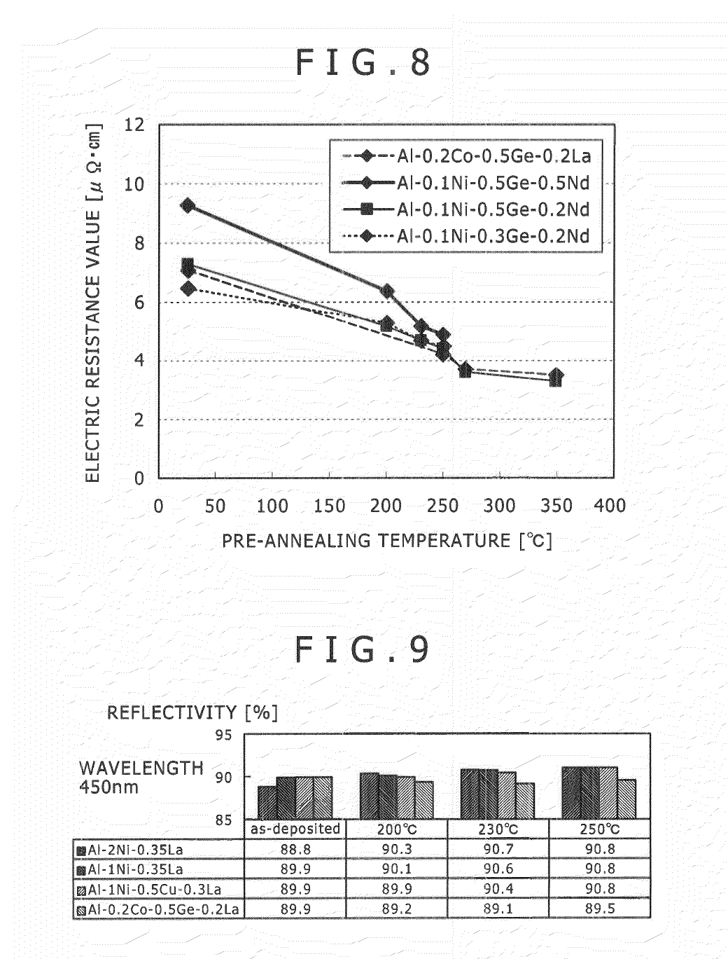

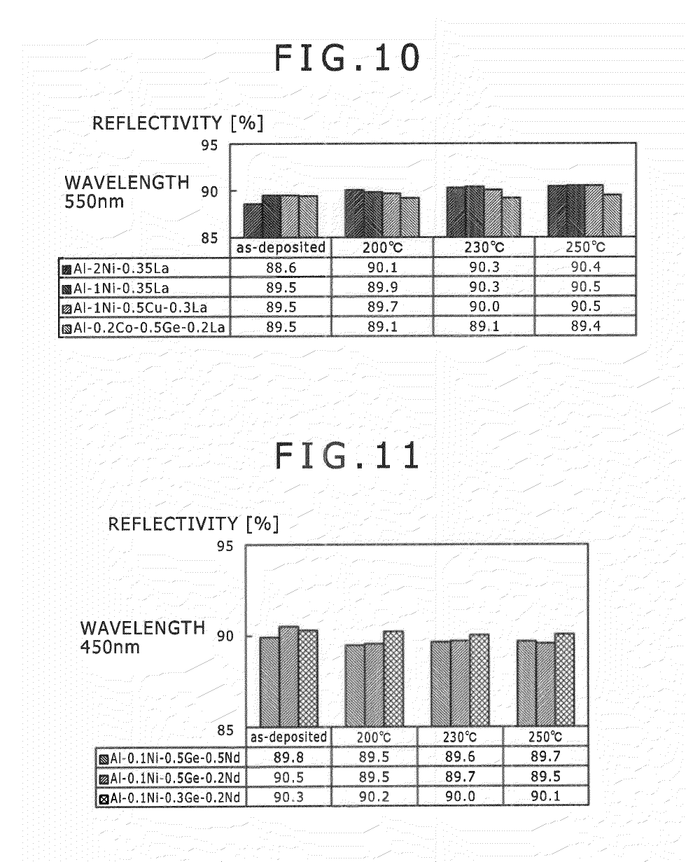

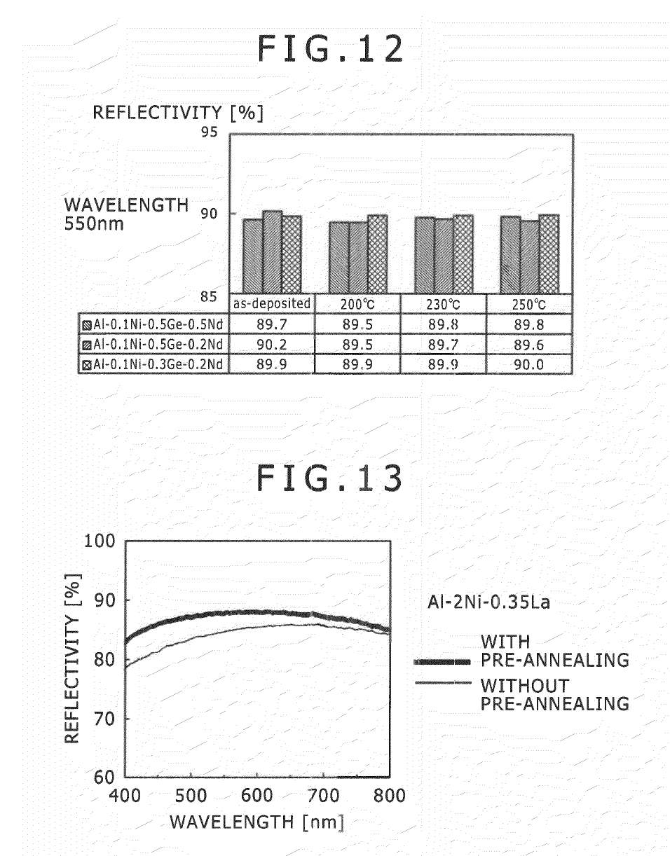

FIGS. 9 to 12 are graphs each showing the relationship between the pre-annealing temperature and the reflectivity of the reflective anode. FIGS. 9 and 11 correspond to the case where the wavelength of light is 450 nm. FIGS. 10 and 12 correspond to the case where the wavelength of light is 550 nm. Incidentally, in this measurement, the basic characterization with the Al-based alloy film alone is performed. Therefore, the reflectivity was measured with no oxide conductive film formed. In all the measurement results, reflectivities as high as around 90% are obtained.

(3) Effects of Pre-Annealing Exerted on Reflectivity

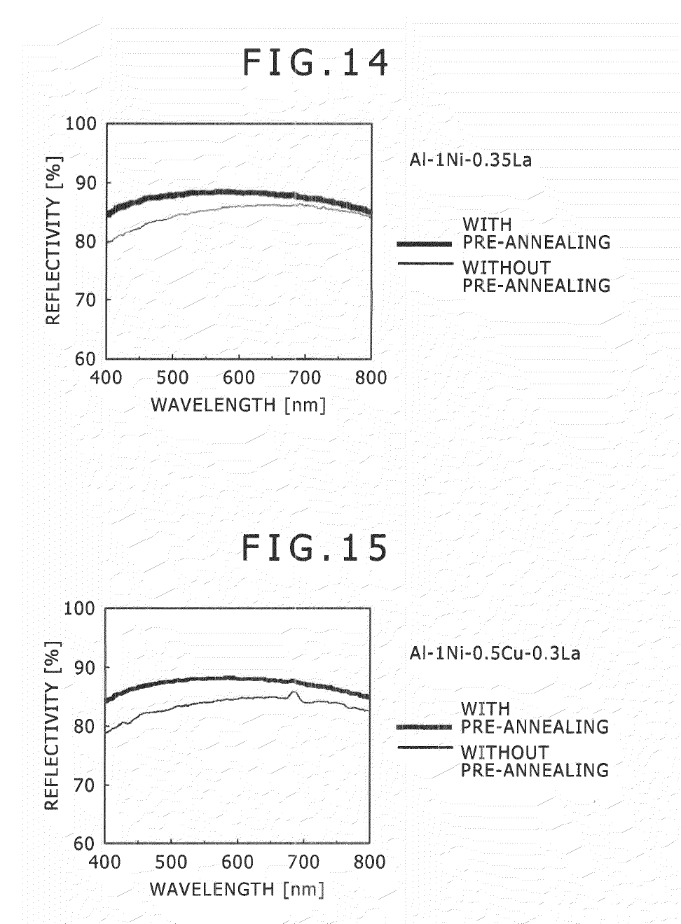

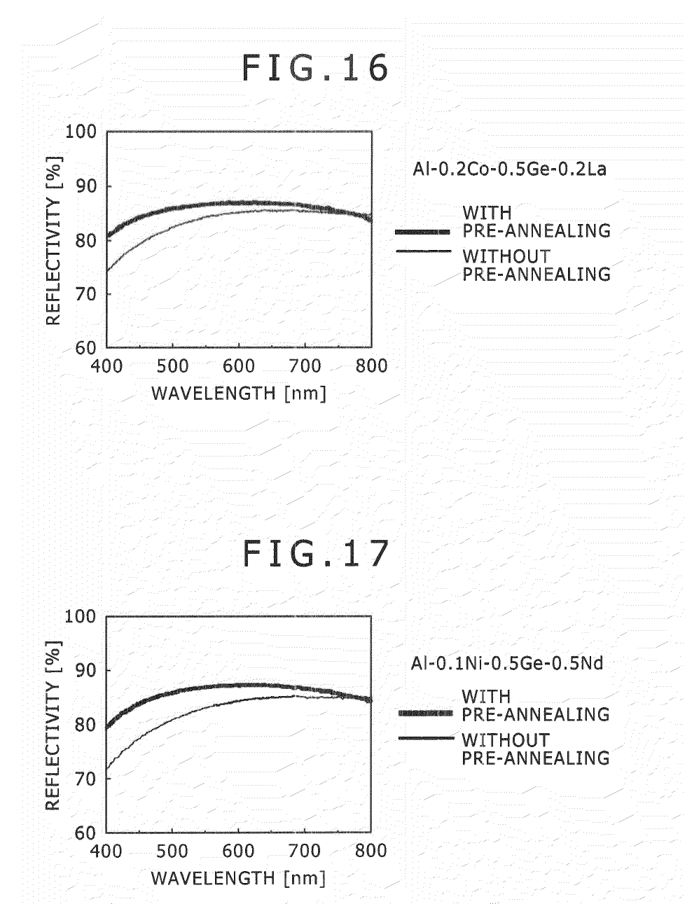

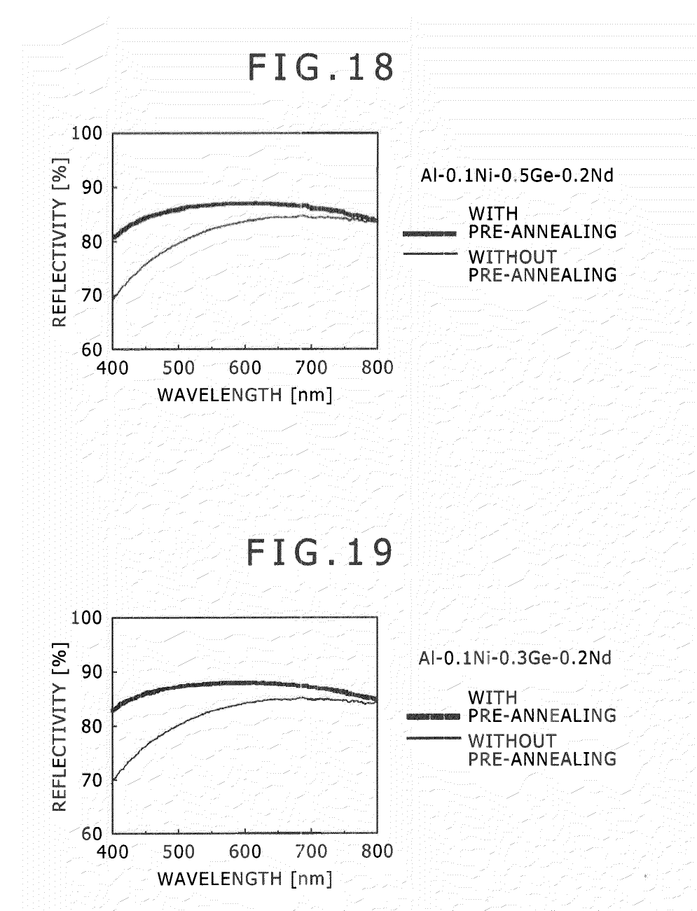

FIGS. 13 to 19 show the results of measurement of the reflectivities of the respective reflective anodes (corresponding to sample Nos. 4-1 to 4-7). All of FIGS. 13 to 19 show that the reflectivity of each reflective anode is improved by performing pre-annealing. The reflectivities in the case of a light wavelength of 450 nm and in the case of 550 nm are shown in Table 6.

TABLE 6

| | | | | With pre-annealing | |
|---|---|---|---|---|---|
| | Composition of | Without pre-annealing | | (250° C. × 30 min.) | |
| Sample No. | reflective anode | Wavelength 450 nm | Wavelength 550 nm | Wavelength 450 nm | Wavelength 550 nm |
| 4-1 | Al—2Ni—0.35La | 81.0% | 84.7% | 86.3% | 88.1% |
| 4-2 | Al—1Ni—0.35La | 82.5% | 85.4% | 87.2% | 88.5% |
| 4-3 | Al—1Ni—0.5Cu—0.3La | 82.0% | 84.3% | 87.1% | 88.4% |
| 4-4 | Al—0.2Co—0.5Ge—0.2La | 79.6% | 84.5% | 84.5% | 86.7% |
| 4-5 | Al—0.1Ni—0.5Ge—0.5Nd | 77.7% | 83.2% | 84.1% | 87.1% |
| 4-6 | Al—0.1Ni—0.5Ge—0.2Nd | 76.0% | 82.5% | 84.8% | 87.1% |
| 4-7 | Al—0.1Ni—0.3Ge—0.2Nd | 75.9% | 82.6% | 85.8% | 87.7% |

(4) Effects of Alkali Solution Treatment Exerted on Reflectivity

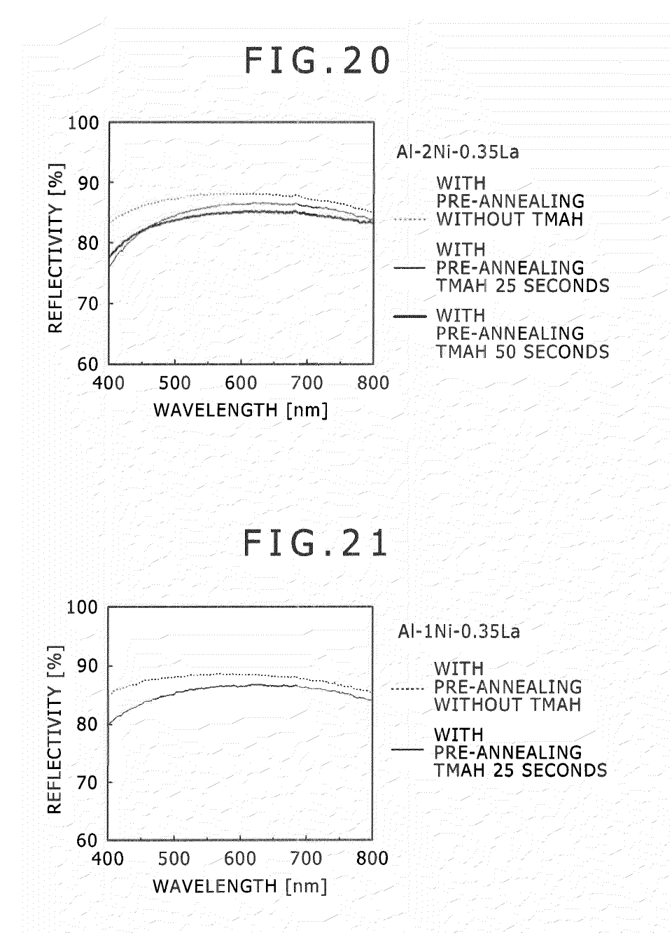

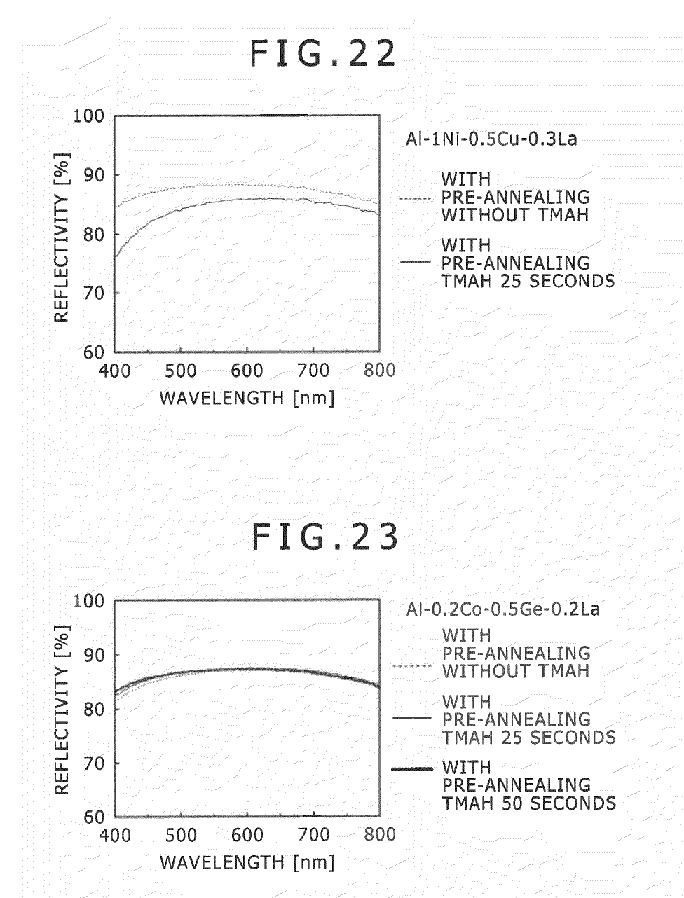

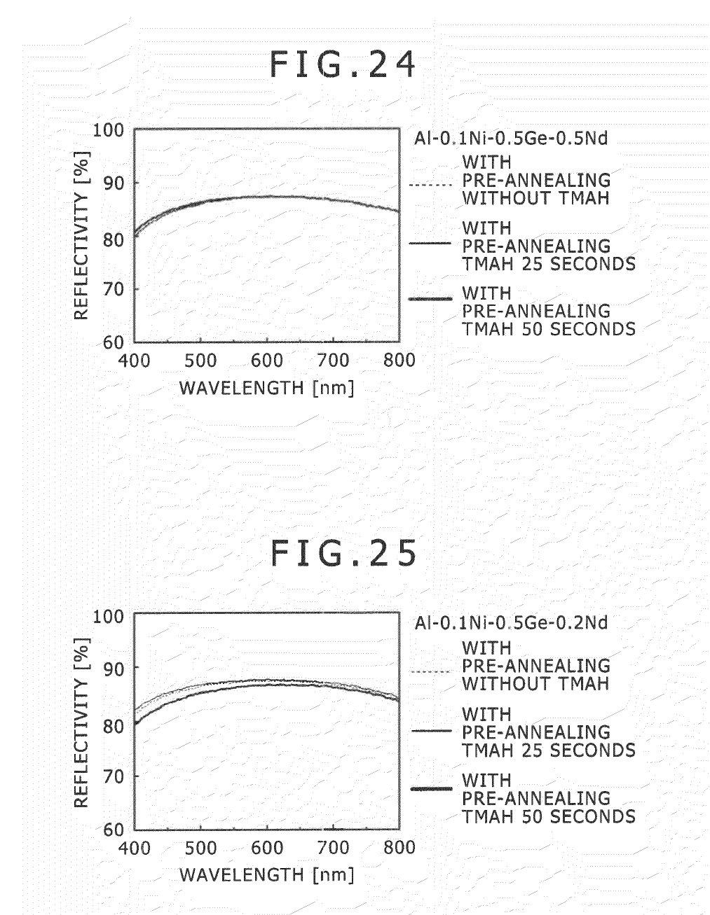

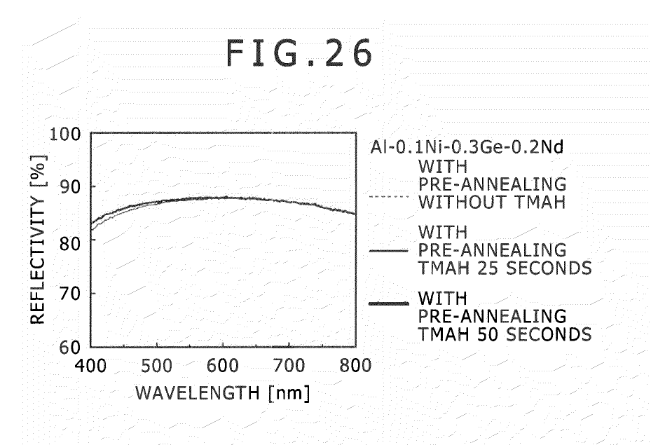

As described in Example 2, when not only pre-annealing but also the TMAH treatment is further performed, the contact resistance value of the reflective anode is largely improved. However, there was a concern about the reduction of the reflectivity due to the TMAH treatment. For this reason, a test of performing the TMAH treatment after pre-annealing was performed. FIGS. 20 to 26 respectively show the reflectivities when only pre-annealing was carried out, and the reflectivities when the TMAH treatment (for 25 seconds or for 50 seconds (except for FIGS. 21 and 22)) was carried out in addition to pre-annealing, for the respective reflective anodes (corresponding to sample Nos. 4-1 to 4-7). All of FIGS. 20 to 26 indicate the following: also by performing the TMAH treatment in addition to pre-annealing, the reflectivity satisfies 85% or more which is the acceptability criterion. Incidentally, the reflectivities in the case of a light wavelength of 450 nm and in the case of 550 nm are shown in Table 7.

TABLE 7

| | | Pre-annealing: | | Pre-annealing: | | Pre-annealing: | |
|---|---|---|---|---|---|---|---|
| | | performed | | performed | | performed | |
| | | TMAH treatment not performed | | TMAH treatment 25 sec | | TMAH treatment 50 sec | |
| Sample | Composition of | Wavelength | Wavelength | Wavelength | Wavelength | Wavelength | Wavelength |
| No. | reflective anode | 450 nm | 550 nm | 450 nm | 550 nm | 450 nm | 550 nm |
| 4-1 | Al—2Ni—0.35La | 86.3% | 88.1% | 81.9% | 86.0% | 82.0% | 84.8% |
| 4-2 | A1—1Ni—0.35La | 87.2% | 88.5% | 83.5% | 86.1% | — | — |
| 4-3 | Al—1Ni—0.5Cu—0.3La | 87.1% | 88.4% | 81.9% | 85.6% | — | — |
| 4-4 | Al—0.2Co—0.5Ge—0.2La | 84.5% | 86.7% | 85.2% | 87.2% | 85.6% | 87.0% |
| 4-5 | Al—0.1Ni—0.5Ge—0.5Nd | 84.1% | 87.1% | 84.2% | 87.2% | 84.6% | 87.3% |
| 4-6 | Al—0.1Ni—0.5Ge—0.2Nd | 84.8% | 87.1% | 85.0% | 87.3% | 83.0% | 86.2% |
| 4-7 | Al—0.1Ni—0.3Ge—0.2Nd | 85.8% | 87.7% | 85.1% | 87.5% | 85.9% | 87.8% |

 Pre-annealing conditions: 250° C., 30 min.

Finally, a study was also conducted on the effects of pre-annealing and the alkali solution treatment exerted on the surface roughnesses (Ra and Rmax). As a result, in any case, it has been confirmed that a problem does no arise in surface roughnesses due to the alkali solution treatment.

As described up to this point, the present application was described in details, and by reference to specific embodiments. However, it is apparent to those skilled in the art that various changes and modifications may be made without departing from the spirit and scope of the present invention. The present application is based on Japanese Patent Application No. 2008-287985 filed on Nov. 10, 2008, and Japanese Patent Application No. 2009-183741 filed on Aug. 6, 2009, the contents of which are incorporated herein by reference.

### DESCRIPTION OF REFERENCE NUMERAL

1 Substrate
2 TFT
3 Passivation film
4 Planarization layer
5 Contact hole
6 Al-based alloy film (Reflective film)
7 Oxide conductive film
8 Organic light-emitting layer
9 Cathode

1. A method for manufacturing a reflective anode for an organic EL display device, comprising:
depositing an Al-based alloy film comprising Ni or Co in an amount of 0.1 to 2 at % on a substrate;
subjecting the Al-based alloy film to a heat treatment at a temperature of 150° C. or more in vacuum or under an inactive gas atmosphere; and
depositing an oxide conductive film so as to be in direct contact with the Al-based alloy film.

2. The method for manufacturing a reflective anode for an organic EL display device according to claim 1, wherein after the heat treatment at 150° C. or more of the Al-based alloy film, and before deposition of the oxide conductive film, the Al-based alloy film is subjected to an alkali solution treatment.

3. A reflective anode for an organic EL display device, comprising:
an oxide conductive film deposited on an Al-based alloy film so as to be in direct contact with the Al-based alloy film,
the Al-based alloy film comprising Ni or Co in an amount of 0.1 to 2 at %, and
the Al-based alloy film having been subjected to a heat treatment at a temperature of 150° C. or more in vacuum or under an inactive gas atmosphere after deposition of the Al-based alloy film and before deposition of the oxide conductive film.

4. The reflective anode for an organic EL display device according to claim 3, wherein the Al-based alloy film further comprises at least one element selected from the group consisting of La, Ge, Cu, Mg, Cr, Mn, Ru, Rh, Pt, Pd, Ir, Ce, Pr, Gd, Tb, Dy, Nd, Ti, Zr, Nb, Mo, Hf, Ta, W, Y, Fe, Sm, Eu, Ho, Er, Tm, Yb, and Lu in a total amount of 0.1 to 2 at %.

5. The reflective anode for an organic EL display device according to claim 4, wherein the Al-based alloy film comprises Nd in an amount of 0.1 to 1 at %.

6. The reflective anode for an organic EL display device according to claim 5, wherein the Al-based alloy film comprises Ge in an amount of 0.1 to 1 at %.

7. The reflective anode for an organic EL display device according to claim 4, wherein the Al-based alloy film comprises Ni and La.

8. The reflective anode for an organic EL display device according to claim 3, wherein the Al-based alloy film further comprises La and Ge and/or Cu in a total amount of 0.1 to 2 at %.

9. The reflective anode for an organic EL display device according to claim 3, wherein the arithmetic mean roughness Ra of the surface on the side of the oxide conductive film opposite to the side thereof in contact with the Al-based alloy film is 2 nm or less.

10. The reflective anode for an organic EL display device according to claim 3, wherein a Ni- or Co-containing precipitate or concentrated layer is formed at the interface of the Al-based alloy film in direct contact with the oxide conductive film.

11. A thin-film transistor substrate comprising the reflective anode according to claim 3.

12. An organic EL display device comprising the thin-film transistor substrate according to claim 11.

13. A sputtering target for forming the reflective anode according to claim 3.
